(19) United States
(12) Patent Application Publication
(10) Pub. No.: US 2018/0097027 A1
(43) Pub. Date: Apr. 5, 2018

(54) IMAGING PANEL AND X-RAY IMAGING DEVICE INCLUDING SAME

(71) Applicant: SHARP KABUSHIKI KAISHA, Sakai City, Osaka (JP)

(72) Inventors: TAKAO SAITOH, Sakai City (JP); SEIJI KANEKO, Sakai City (JP); YUTAKA TAKAMARU, Sakai City (JP); YOHSUKE KANZAKI, Sakai City (JP)

(21) Appl. No.: 15/567,254

(22) PCT Filed: Apr. 13, 2016
(86) PCT No.: PCT/JP2016/061890

§ 371 Date: Oct. 17, 2017

(30) Foreign Application Priority Data
Apr. 17, 2015 (JP) 2015-084981

(51) Int. Cl. H01L 27/146; G01T 1/20; G01T 1/24; H04N 5/32; H01L 29/786

(52) U.S. Cl. CPC H01L 27/14612; G01T 1/20; H01L 29/7869; G01T 1/247; H04N 5/32; H01L 27/14663

(57) ABSTRACT

Provided is an imaging panel and an imaging device with which the amount of irradiated X-ray can be reduced, and at the same time, the threshold voltage of a TFT during X-ray irradiation can be prevented from shifting. The imaging panel includes an imaging part that includes a plurality of pixels 13 that generate charges based on X-ray projected from an X-ray source, and a thin film transistor 14 for reading out the charges generated at the pixel 13. The thin film transistor 14 has a gate 141 and an oxide semiconductor layer 142, as well as a source 143S and a drain 143D formed on a part of the oxide semiconductor layer 142 by wet etching with respect to a metal film formed on the oxide semiconductor layer 142. The oxide semiconductor layer 142 contains indium, tin, gallium, and oxygen.

### TECHNICAL FIELD

The present invention relates to an imaging panel and an X-ray imaging device including the same.

### BACKGROUND ART

An X-ray imaging device has been known that picks up an X-ray image by using an imaging panel that includes a plurality of pixels. Patent Document 1 shown below discloses an X-ray sensor in which each pixel includes a thin film transistor (TFT) made of an oxide semiconductor, and a photodiode. To form the TFT of this X-ray sensor, an oxide semiconductor containing indium, gallium, zinc, and oxygen is used.

### PRIOR ART DOCUMENT

### Patent Document

Patent Document 1: JP-A-2013-30682

### SUMMARY OF THE INVENTION

### Problem to be Solved by the Invention

Incidentally, the source and the drain of the TFT in which an oxide semiconductor containing indium, gallium, zinc, and oxygen is used are formed by forming a film of a metal such as aluminum on the oxide semiconductor and subjecting the metal film to dry-etching. An oxide semiconductor containing indium, gallium, zinc, and oxygen has a low acid etching resistance, and hence, it is difficult to carry out wet etching using an acid etching solution suitable for etching aluminum o the like. Dry etching is therefore often used for forming a source and a drain. When, however, etching damage occurs due to dry etching on the surface of the oxide semiconductor, defect levels are formed at an interface between the oxide semiconductor and an insulating film such as a silicon nitride film formed on the oxide semiconductor. Defect levels cause the threshold value of the TFT to shift toward the negative direction, thereby making it difficult to cause the TFT to stably operate.

Besides, though the oxide semiconductor containing indium, gallium, zinc, and oxygen has a high electron mobility as compared with an amorphous semiconductor, it is desirable to use an oxide semiconductor that has a further higher electron mobility, in order to further reduce the amount of X-ray irradiated on an object.

It is an object of the present invention to provide an imaging panel and an imaging device with which the amount of irradiated X-ray can be reduced, and at the same time, the threshold voltage of the TFT during X-ray irradiation can be prevented from shifting.

### Means to Solve the Problem

An imaging panel according to the present invention includes: an imaging part that includes a pixel that receives X-ray and outputs charges corresponding to the received X-ray; and a thin film transistor for reading out the charges at the pixel. The thin film transistor includes: a gate; an oxide semiconductor layer; and a source and a drain formed on a part of the oxide semiconductor layer, the source and the drain being formed by wet etching with respect to a metal film formed on the oxide semiconductor layer, wherein the oxide semiconductor layer includes an ITZO layer that contains indium, tin, gallium, and oxygen.

### Effect of the Invention

With the configuration of the present invention, the amount of irradiated X-ray can be reduced, and at the same time, the threshold voltage of the TFT during X-ray irradiation can be prevented from shifting.

### BRIEF DESCRIPTION OF DRAWINGS

FIG. 1 is a schematic diagram illustrating an X-ray imaging device in an embodiment.

FIG. 2 is a schematic diagram illustrating a schematic configuration of the imaging panel illustrated in FIG. 1.

FIG. 3 is a plan view illustrating a pixel of the imaging panel illustrated in FIG. 2.

FIG. 4 is a cross-sectional view illustrating the pixel illustrated in FIG. 2 taken along line A-A.

FIG. 5 is a cross-sectional view illustrating a step for producing the gate electrode and the gate insulating film illustrated in FIG. 4.

FIG. 6 is a cross-sectional view illustrating a step for producing the oxide semiconductor layer, the source electrode, and the drain electrode illustrated in FIG. 4.

FIG. 7 is a cross-sectional view illustrating a step for producing the interlayer insulating film illustrated in FIG. 4.

FIG. 8 is a cross-sectional view illustrating a step for producing the flattening film illustrated in FIG. 4.

FIG. 9 is a cross-sectional view illustrating a step for producing the photodiode illustrated in FIG. 4.

FIG. 10 is a cross-sectional view illustrating a step for producing the upper electrode illustrated in FIG. 4.

FIG. 11 is a cross-sectional view illustrating a step for producing the bias line and the protection film illustrated in FIG. 4.

FIG. 12A illustrates results of measurement of the threshold voltage of a TFT before and after X-ray irradiation in order to clarify the shift amount of the threshold voltage, in a case where the source electrode and the drain electrode of the TFT are formed by using dry etching.

FIG. 12B illustrates results of measurement of the threshold voltage of the TFT in Embodiment 1 before and after X-ray irradiation in order to clarify the shift amount of the threshold voltage.

FIG. 13 is a cross-sectional view illustrating a configuration of a TFT in Embodiment 2.

FIG. 14A is a cross-sectional view illustrating a step for producing the source electrode and the drain electrode of the TFT illustrated in FIG. 13.

FIG. 14B is a cross-sectional view illustrating a step for producing the source electrode and the drain electrode of the TFT illustrated in FIG. 13.

FIG. 15 is a cross-sectional view of a pixel in Embodiment 3.

FIG. 16A is a cross-sectional view illustrating a step for producing a conductive film illustrated in FIG. 15.

FIG. 16B is a cross-sectional view illustrating a step for producing a photodiode illustrated in FIG. 15.

FIG. 17A illustrates results of measurement of the threshold voltage of the TFT before and after X-ray irradiation in order to clarify the shift amount of the threshold voltage in a case where the conductive film in Embodiment 3 is not provided on the back channel side.

FIG. 17B illustrates results of measurement of the threshold voltage of the TFT in Embodiment 3 before and after X-ray irradiation in order to clarify the shift amount of the threshold voltage.

FIG. 18 is a cross-sectional view of a TFT in Embodiment 4.

FIG. 19 illustrates results of measurement of the threshold voltage of the TFT in Modification Example (3) before and after X-ray irradiation in order to clarify the shift amount of the threshold voltage.

### MODE FOR CARRYING OUT THE INVENTION

An imaging panel according to an embodiment of the present invention includes: an imaging part that includes a pixel that receives X-ray and outputs charges corresponding to the received X-ray; and a thin film transistor for reading out the charges at the pixel. The thin film transistor includes: a gate; an oxide semiconductor layer; and a source and a drain formed on a part of the oxide semiconductor layer, the source and the drain being formed by wet etching with respect to a metal film formed on the oxide semiconductor layer, wherein the oxide semiconductor layer includes an ITZO layer that contains indium, tin, gallium, and oxygen.

In the first configuration, the imaging panel includes an imaging part and a thin film transistor. The imaging part includes a pixel that outputs charges based on X-ray. Charges at the pixel are read out through the thin film transistor. The thin film transistor includes a gate and an oxide semiconductor layer, as well as a source and a drain that are formed on a part of the oxide semiconductor layer by wet etching with respect to a metal film formed on the oxide semiconductor layer. The oxide semiconductor layer includes an ITZO layer that contains indium, tin, gallium, and oxygen. With this configuration, the amount of irradiated X-ray can be reduced, since the ITZO layer has a high electron mobility. Besides, since the source and the drain are formed by using wet etching, it is less likely that etching damage would occur to the oxide semiconductor layer, as compared with a case where the source and the drain are formed by using dry etching. As a result, it is less likely that the threshold voltage of the thin film transistor would shift toward the negative direction, which makes it possible to reduce the amount of shift of the threshold voltage during X-ray irradiation.

The second configuration may be the first configuration further characterized in that the oxide semiconductor layer further includes a semiconductor layer that is provided on the ITZO layer and contains indium and oxygen, as well as at least one of tin, zinc, gallium, and tungsten.

According to the second configuration, the source and the drain are formed on a part of the semiconductor layer by carrying out wet etching with respect to the metal film formed on the semiconductor layer. This makes it possible that the channel area in the ITZO layer should be protected by the semiconductor layer from etching damage, and therefore, the shift amount of the threshold voltage of the thin film transistor can be reduced.

The third configuration may be the first configuration or the second configuration further characterized by further including an insulating film provided on the thin film transistor and a conductive part provided at a position opposed to the thin film transistor, in an upper layer above the insulating film, and the conductive part may be connected with the gate or the source through a contact hole formed in the insulating film.

In the third configuration, carriers (holes) trapped by defect levels formed between the insulating film and the oxide semiconductor layer are recombined with carriers (electrons) induced in the insulating film on the oxide semiconductor layer depending on the potential of the conductive part. As a result, carriers trapped at the interface between the insulating film and the oxide semiconductor layer are reduced, whereby the threshold voltage of the thin film transistor can be prevented from shifting toward the negative direction.

An imaging panel according to an embodiment of the present invention includes: an imaging part that includes a pixel that receives X-ray and outputs charges corresponding to the received X-ray; a thin film transistor for reading out the charges at the pixel; an insulating film provided on the thin film transistor; and a conductive part provided at a position opposed to the thin film transistor, in an upper layer above the insulating film. The thin film transistor includes: a gate; an oxide semiconductor layer; a source provided on the oxide semiconductor layer; and a drain provided on the oxide semiconductor layer. In the imaging panel, the oxide semiconductor layer includes an ITZO layer that contains indium, tin, gallium, and oxygen; and the conductive part is connected with the gate or the source through a contact hole formed in the insulating film (the fourth configuration).

In the fourth configuration, the imaging panel includes an imaging part, a thin film transistor, an insulating film, and a conductive part. The imaging part includes a pixel that outputs charges based on the X-ray, and the charges at the pixel are read out through the thin film transistor. The oxide semiconductor layer of the thin film transistor includes an ITZO layer that contains indium, tin, gallium, and oxygen. With this configuration, the amount of irradiated X-ray can be reduced, since the ITZO layer has a high electron mobility. Further, in the fourth configuration, the conductive part is provided at a position opposed to the oxide semiconductor layer of the thin film transistor, in an upper layer above the insulating film, and is connected with the gate or the source through a contact hole formed in the insulating film. With this configuration, therefore, carriers (holes) trapped by defect levels formed between the insulating film and the oxide semiconductor layer are recombined with carriers (electrons) induced in the insulating film on the oxide semiconductor layer depending on the potential of the conductive part. As a result, carriers trapped at the interface between the insulating film and the oxide semiconductor layer are reduced, whereby the threshold voltage of the thin film transistor can be prevented from shifting toward the negative direction.

The fifth configuration may be the fourth configuration further characterized in that the oxide semiconductor layer further includes a semiconductor layer that is provided on the ITZO layer and contains indium and oxygen, as well as at least one of tin, zinc, gallium, and tungsten.

According to the fifth configuration, a semiconductor layer is further provided on the ITZO layer. In a case where, therefore, the source and the drain are formed by dry etching or wet etching, the channel area in the oxide semiconductor layer can be protected from etching damage.

An X-ray imaging device according to an embodiment of the present invention includes: the imaging panel of any one of the first to fifth configurations; an X-ray source that projects X-ray to the imaging panel; and a control unit that controls a gate voltage of the thin film transistor in the imaging panel, and reads out a signal corresponding to charges generated at the pixel in the imaging panel (the sixth configuration).

The following description describes embodiments of the present invention in detail, while referring to the drawings. Identical or equivalent parts in the drawings are denoted by the same reference numerals, and the descriptions of the parts are not repeated.

### Embodiment 1

### (Configuration)

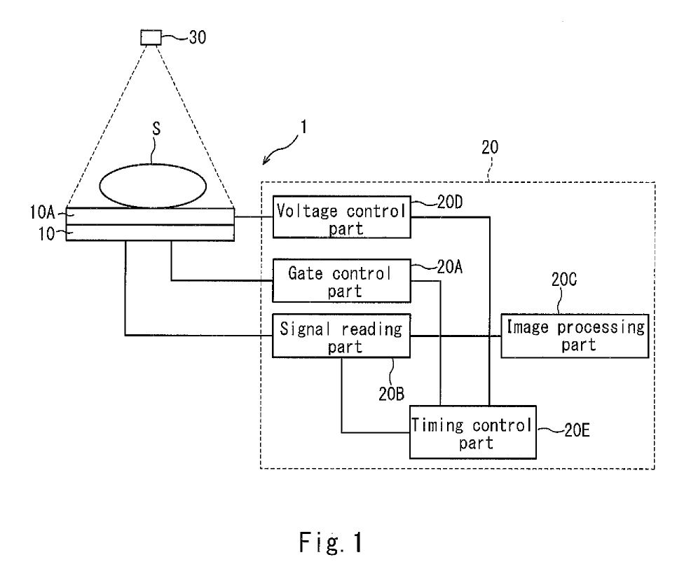

FIG. 1 is a schematic diagram illustrating an X-ray imaging device in Embodiment 1. The X-ray imaging device 1 includes an imaging panel 10, a scintillator 10A, a control unit 20, and an X-ray source 30. X-ray is projected from the X-ray source 30 to a subject S, and X-ray having passed through the subject S is converted into fluorescence (hereinafter referred to as scintillation light) by the scintillator 10A arranged over the imaging panel 10. The X-ray imaging device 1 obtains an X-ray image by picking up the scintillation light with use of the imaging panel 10 and the control unit 20.

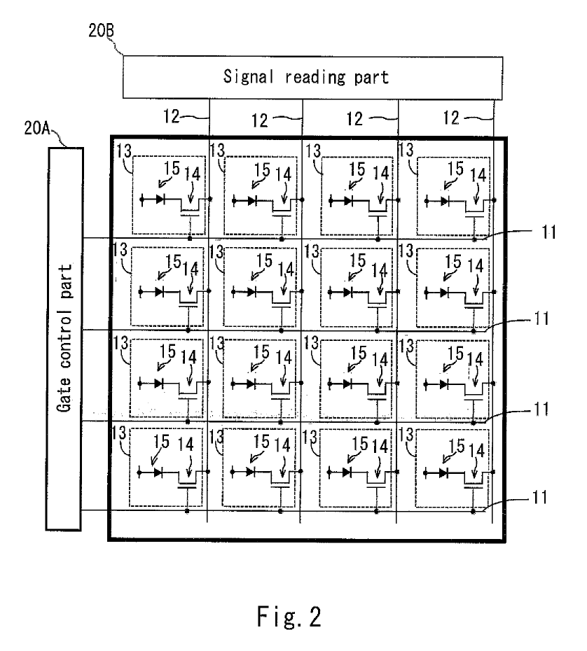

FIG. 2 is a schematic diagram illustrating a schematic configuration of the imaging panel 10. As illustrated in FIG. 2, a plurality of gate lines 11 and a plurality of data lines 12 that intersect with the gate lines 11 are formed in the imaging panel 10. The imaging panel 10 includes a plurality of areas 13 that are defined by the gate lines 11 and the data line 12 (these areas are hereinafter referred to as pixels). FIG. 2 illustrates an example in which sixteen (4×4) pixels 13 are provided, but the number of pixels in the imaging panel 10 is not limited to this.

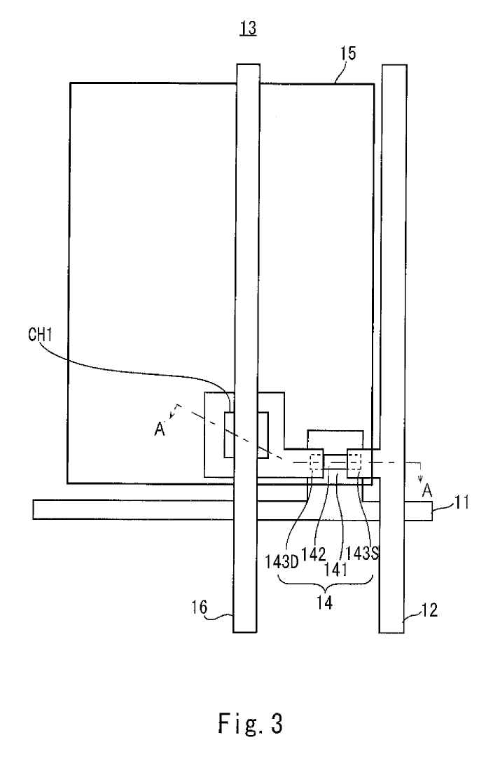

Each pixel 13 is provided with a thin film transistor (TFT) 14 connected to the gate line 11 and the data line 12 and a photodiode 15 connected to the TFT 14. Further, though the illustration is omitted in FIG. 2, each pixel 13 is provided with a bias line 16 (see FIG. 3) for supplying a bias voltage to the photodiode 15, in such a form that the bias line 16 is approximately parallel to the data line 12.

In each pixel 13, scintillation light obtained by converting X-ray having passed through the subject S is converted by the photodiode 15 into charges in accordance with the amount of the light.

The gate lines 11 in the imaging panel 10 are switched sequentially to a selected state one by one by a gate control part 20A, and the TFTs 14 connected to the gate line 11 in the selected state are turned ON. When the TFTs 14 shift to the ON state, data signals corresponding to charges obtained by conversion by the photodiode 15 are output via the data lines 12 to a signal reading part 20B.

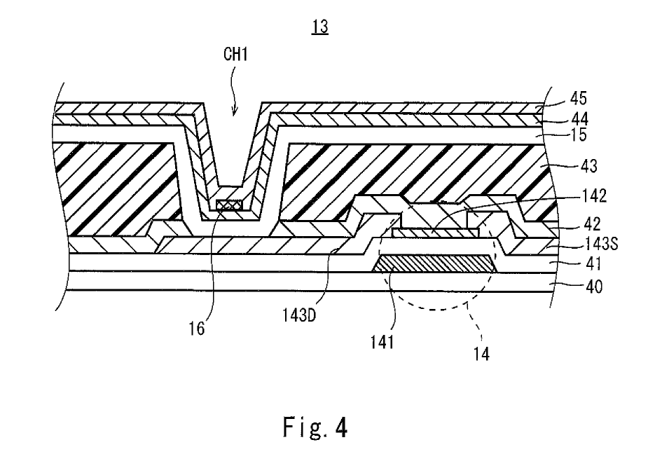

Next, the following description describes a specific configuration of the pixel 13. FIG. 3 is a plan view illustrating the pixel 13 of the imaging panel 10 illustrated in FIG. 2. Further, FIG. 4 is a cross-sectional view of the pixel illustrated in FIG. 3 taken along line A-A.

As illustrated in FIG. 4, the pixel 13 is formed on a substrate 40. The substrate 40 is, for example, a substrate having insulating properties, such as a glass substrate, a silicon substrate, a plastic substrate having heat-resisting properties, or a resin substrate. In particular, polyethylene terephthalate (PET), polyethylene naphthalate (PEN), polyether sulfone (PES), acryl, polyimide, or the like may be used for a plastic substrate or a resin substrate.

The TFT 14 includes a gate electrode 141, an oxide semiconductor layer 142 arranged on the gate electrode 141 with a gate insulating film 41 being interposed therebetween, and a source electrode 143S as well as a drain electrode 143D connected to the oxide semiconductor layer 142.

The gate electrode 141 is formed in contact with one of surfaces in the thickness direction of the substrate 40. The gate electrode 141 is composed of a branch of the gate line 11 that is branched in a direction in which the data line 12 extends, as illustrated in FIG. 3, and is formed in contact with a surface of the substrate 40, the surface being one of the surfaces in the thickness direction, as illustrated in FIG. 4. The gate electrode 141 is made of, for example, a metal such as aluminum (Al), tungsten (W), molybdenum (Mo), tantalum (Ta), chromium (Cr), titanium (Ti), or copper (Cu), an alloy of any of these metals, or a nitride of any of these metals. Further, the gate electrode 141 may be, for example, a laminate of a plurality of metal films.

As illustrated in FIG. 4, the gate insulating film 41 is formed on the substrate 40, covering the gate electrode 141. To form the gate insulating film 41, for example, silicon oxide (SiOₓ), silicon nitride (SiNₓ), silicon oxide nitride (SiOₓN_{y}) (x>y), silicon nitride oxide (SiNₓO_{y}) (x>y), or the like, may be used.

In order to prevent diffusion of impurities and the like from the substrate 40, the gate insulating film 41 may have a laminate structure. For example, silicon nitride (SiNₓ), silicon nitride oxide (SiNₓO_{y}) (x>y), or the like may be used in a lower layer; and silicon oxide (SiOₓ), silicon oxide nitride (SiOₓN_{y}) (x>y), or the like may be used in an upper layer. Further, in order that a fine gate insulating film that allows a smaller gate leakage current is formed at a low film forming temperature, a noble gas element such as argon may be contained in a reaction gas so as to be included in the insulating film.

As illustrated in FIG. 4, the oxide semiconductor layer 142 is formed in contact with the gate insulating film 41. The oxide semiconductor layer 142 contains an oxide semiconductor that contains indium (In), gallium (Ga), and zinc (Zn) at a predetermined ratio (hereinafter referred to as a first oxide semiconductor layer). As the first oxide semiconductor layer 142, a microcrystalline-type oxide semiconductor in which an amorphous state and a polycrystalline state are present mixedly may be used, or an oxide semiconductor in which no impurity element is added may be used.

The source electrode 143S and the drain electrode 143D are formed in contact with the first oxide semiconductor layer 142 and the gate insulating film 41. As illustrated in FIG. 3, the source electrode 143S is composed of a branch of the data line 12 that is branched in a direction in which the gate line 11 extends. As illustrated in FIG. 4, the drain electrode 143D is connected to the photodiode 15 through the contact hole CH1. The drain electrode 143D functions as a drain electrode of the TFT 14, and also functions as a lower electrode of the photodiode 15.

The source electrode 143S, and the drain electrode 143D are formed in an identical layer. The source electrode 143S and the drain electrode 143D are made of, for example, a metal such as aluminum (Al), tungsten (W), molybdenum (Mo), tantalum (Ta), chromium (Cr), titanium (Ti), copper (Cu) or the like, or an alloy of any of these, or nitride of any of these metals. Further, as a material for the source electrode 143S and the drain electrode 143D, the following may be used: a material having translucency such as indium tin oxide (ITO), indium zinc oxide (IZO), indium tin oxide (ITSO) containing silicon oxide, indium oxide (In₂O₃), tin oxide (SnO₂), zinc oxide (ZnO), or titanium nitride; or an appropriate combination of any of these. The source electrode 143S and the drain electrode 143D may be obtained by, for example, laminating a plurality of metal films.

The interlayer insulating film 42 covers the oxide semiconductor layer 142, the source electrode 143S, and the drain electrode 143D. The interlayer insulating film 42 may have a single layer structure made of silicon oxide (SiO₂) or silicon nitride (SiN), or a laminate structure obtained by laminating silicon nitride (SiN) and silicon oxide (SiO₂) in this order. In the present embodiment, the interlayer insulating film 42 has a film thickness of, for example, about 0.5 μm.

The flattening film 43 is formed on the interlayer insulating film 42, so as to cover the interlayer insulating film 42. As a material for the flattening film 43, for example, an organic resin such as polyimide can be used. In the present embodiment, the flattening film 43 has a film thickness of, for example, about 2 to 3 μm.

The photodiode 15 covers the flattening film 4, and is formed in contact with the drain electrode 143D via the contact hole CH1 that passes through the organic film 43 and the interlayer insulating film 42. The photodiode 15 includes an n-type amorphous silicon layer, an intrinsic amorphous silicon layer, and a p-type amorphous silicon layer (neither illustrated). The n-type amorphous silicon layer is made of amorphous silicon in which an n-type impurity (for example, phosphorus) is doped. The n-type amorphous silicon layer is formed in contact with the drain electrode 143D. The n-type amorphous silicon layer has a thickness of, for example, 20 to 100 nm. The intrinsic amorphous silicon layer is made of intrinsic amorphous silicon. The intrinsic amorphous silicon layer is formed in contact with the n-type amorphous silicon layer. The intrinsic amorphous silicon layer has a thickness of, for example, 200 to 2000 nm. The p-type amorphous silicon layer is made of amorphous silicon in which p-type an impurity (for example, boron) is doped. The p-type amorphous silicon layer is formed in contact with the intrinsic amorphous silicon layer. The p-type amorphous silicon layer has a thickness of, for example, 10 to 50 nm.

The electrode 44 is formed on the photodiode 15, and functions as an upper electrode of the photodiode 15. The electrode 44 supplies the voltage of the bias line 16 described below as a reference voltage (bias voltage) in the photoelectric conversion, to the photodiode 15. As a material for forming the electrode 44, for example, a transparent conductive film of indium tin oxide (ITO), indium zinc oxide (IZO), or the like can be used.

The bias line 16 is formed on the electrode 44, and as illustrated in FIG. 3, the bias line 16 is formed approximately in parallel to the data line 12. The bias line 16 is connected to a voltage control part 20D (see FIG. 1). The bias line 16 applies a bias voltage supplied from the voltage control part 20D to the electrode 44. The bias line 16 has a laminate structure obtained by laminating, for example, indium zinc oxide (IZO) and molybdenum (Mo).

The protection film 45 is formed so as to cover the electrode 44 and the bias line 16. The protection film 45 may have a single layer structure made of silicon oxide (SiO₂) or silicon nitride (SiN), or alternatively, may have a laminate structure obtained by laminating silicon nitride (SiN) and silicon oxide (SiO₂) in this order.

Though the illustration is omitted in FIG. 4, a scintillator 10A (see FIG. 1) is provided on the imaging panel 10, that is, on the protection film 45.

Referring to FIG. 1 again, the following describes the configuration of the control unit 20. The control unit 20 includes the gate control part 20A, the signal reading part 20B, an image processing part 20C, the voltage control part 20D, and a timing control part 20E.

As illustrated in FIG. 2, a plurality of the gate lines 11 are connected to the gate control part 20A. The gate control part 20A applies a predetermined gate voltage, through the gate lines 11, to the TFTs 14 that are connected to the gate lines 11.

As illustrated in FIG. 2, a plurality of the data lines 12Are connected to the signal reading part 20B. Through the respective data lines 12, the signal reading part 20B reads out data signals corresponding to charges obtained by conversion by the photodiodes 15 that the pixels 13 include. The signal reading part 20B generates image signals based on the data signals, and outputs the same to the image processing part 20C.

The image processing part 20C generates an X-ray image signal based on the image signals output from the reading part 20B.

The voltage control part 20D is connected to the bias lines 16 (see FIG. 3). The voltage control part 20D applies a predetermined bias voltage to the bias lines 16. This allows a bias voltage to be applied to the photodiodes 15 through the electrodes 44 connected to the bias lines 16.

The timing control part 20E controls timings of operations of the gate control part 20A, the signal reading part 20B, and the voltage control part 20D.

The gate control part 20A selects one gate line 11 from among a plurality of the gate lines 11, based on the control signal from the timing control part 20E. The gate control part 20A applies a predetermined gate voltage, through the selected gate line 11, to the TFTs 14 that are connected to the selected gate line 11.

The signal reading part 20B selects one data line 12 from among a plurality of the data lines 12 based on the control signal from the timing control part 20E. Through the selected data line 12, the signal reading part 20B reads out a data signal corresponding to charges obtained by conversion by the photodiode 15 in the pixel 13. The pixel 13 from which a data signal is read out is connected to the data line 12 selected by the signal reading part 20B, and is connected to the gate line 11 selected by the gate control part 20A.

The timing control part 20E, for example, outputs a control signal to the voltage control part 20D when X-ray is emitted from the X-ray source 30. Based on this control signal, the voltage control part 20D applies a predetermined bias voltage to the electrode 44.

### (Operation of X-Ray Imaging Device 1)

First, X-ray is emitted by the X-ray source 30. Here, the timing control part 20E outputs a control signal to the voltage control part 20D. More specifically, for example, a signal that indicates that X-ray is emitted from the X-ray source 30 is output from the control device that controls operations of the X-ray source 30, to the timing control part 20E. When this signal is input to the timing control part 20E, the timing control part 20E outputs the control signal to the voltage control part 20D. The voltage control part 20D applies a bias voltage to the bias line 16 based on the control signal from the timing control part 20E.

The X-ray emitted from the X-ray source 30 passes through the subject S, and becomes incident on the scintillator 10A. The X-ray incident on the scintillator 10A is converted to scintillation light, and the scintillation light becomes incident on the imaging panel 10.

When the scintillation light becomes incident on the photodiode 15 provided in each pixel 13 in the imaging panel 10, the scintillation light is converted by the photodiode 15 into charges corresponding to the amount of the scintillation light.

A data signal corresponding to the charges obtained by conversion by the photodiode 15 is read out by the signal reading part 20B through the data line 12 when the TFT 14 is caused to be in an ON state in response to a gate voltage (positive voltage) that is output from the gate control part 20A through the gate line 11. An X-ray image corresponding to the data signal thus read out is generated by the image processing part 20C.

### (Method for Producing Imaging Panel 10)

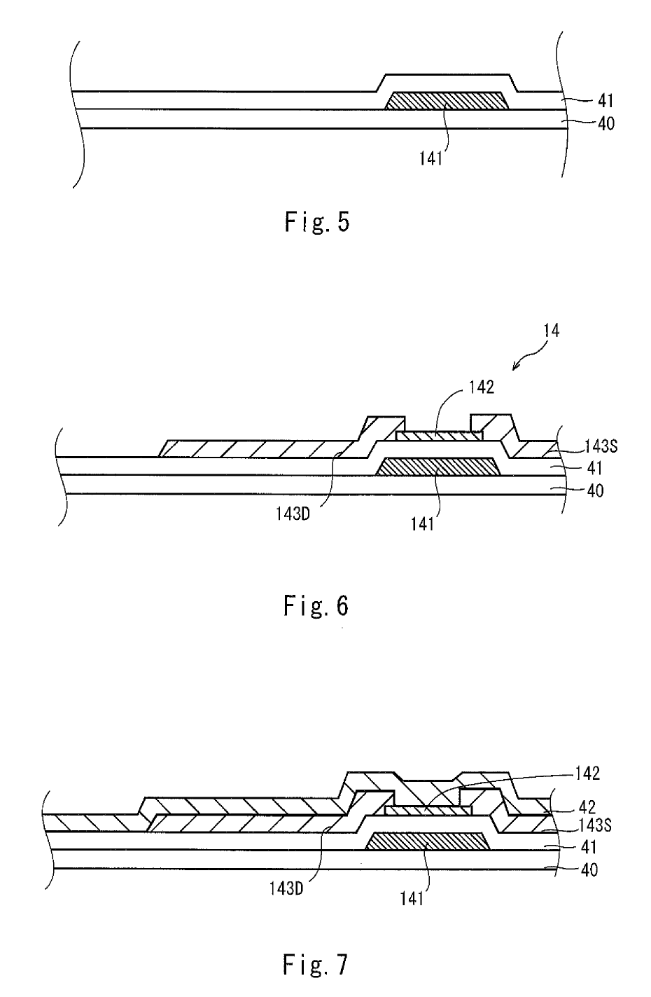

Next, the following describes a method for producing the imaging panel 10. FIGS. 5 to 11 are cross-sectional views illustrating the pixel 13 in respective steps of the method for producing the imaging panel 10.

At the step illustrated in FIG. 5, first, a metal film is formed on the substrate 40, which is obtained by laminating aluminum and titanium by sputtering or the like. Then, this metal film is patterned by photolithography, whereby the gate electrode 141 is formed. The gate electrode 141 has a thickness of, for example, 300 nm.

After the gate electrode 141 is formed, the gate insulating film 41 made of silicon oxide (SiOₓ), silicon nitride (SiNₓ), or the like is formed on the substrate 40 by plasma CVD, sputtering, or the like, so as to cover the gate electrode 141. The gate insulating film 41 has a thickness of, for example, 20 to 150 nm.

Subsequently, at the step illustrated in FIG. 6, a film of oxide semiconductor containing indium (In), tin (Sn), and gallium (Ga) is formed on the gate insulating film 41 by, for example, sputtering, and the oxide semiconductor is patterned by photolithography, whereby the first oxide semiconductor layer 142 is formed. After the first oxide semiconductor layer 142 is formed, it may be subjected to heat treatment in an atmosphere containing oxygen (for example, in the ambient atmosphere) at a high temperature (for example, at 350° C. or higher). In this case, oxygen defects in the first oxide semiconductor layer 142 can be decreased. The first oxide semiconductor layer 142 has a thickness of, for example, 5 to 100 nm.

Next, after the first oxide semiconductor layer 142 is formed, for example, a metal film containing aluminum is formed on the gate insulating film 41, and on the oxide semiconductor layer 142, by sputtering or the like. Then, this metal film is patterned by photolithography, and is subjected to wet etching with use of an inorganic acid etching liquid containing phosphoric acid, nitric acid, acetic acid, or the like. Through this process, the source electrode 143S, the data line 12 and the drain electrode 143D are formed, whereby the bottom gate type TFT 14 is formed. The thickness of the source electrode 143S and the drain electrode 143D is, for example, 50 to 500 nm.

Next, at the step illustrated in FIG. 7, the interlayer insulating film 42 made of silicon oxide (SiO₂) or silicon nitride (SiN) is formed by, for example, plasma CVD, on the source electrode 143S and the drain electrode 143D.

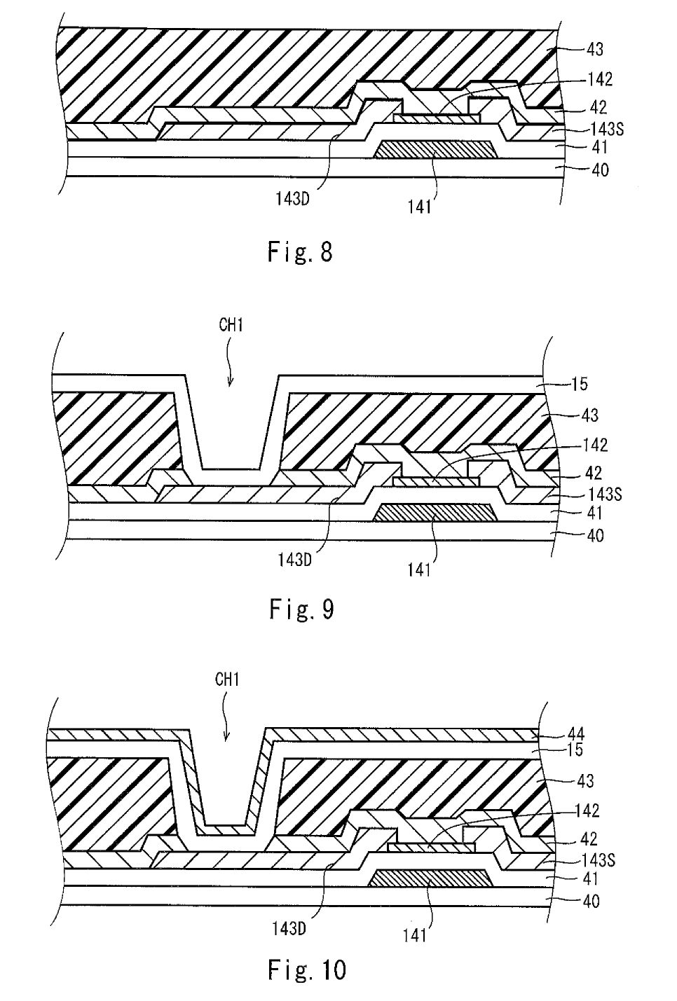

After the interlayer insulating film 42, at the step illustrated in FIG. 8, the flattening film 43 containing an organic resin such as polyimide is formed on the interlayer insulating film 42 by plasma CVD. In the present embodiment, the flattening film 43 has a thickness of, for example, 2 to 3 μm.

After the flattening film 43 is formed, at the step illustrated in FIG. 9, the film is patterned by photolithography, whereby a contact hole CH1 that passes through the flattening film 43 and the interlayer insulating film 42 is formed on the drain electrode 143D. Then, an n-type amorphous silicon layer, an intrinsic amorphous silicon layer, and a p-type amorphous silicon layer are formed in this order on the flattening film 43 by sputtering or the like. Thereafter, patterning by photolithography is performed, followed by dry etching, whereby the photodiode 15 is formed. This causes the photodiode 15 and the drain electrode 143D to be connected via the contact hole CH1.

Subsequently, at the step illustrated in FIG. 10, a film of indium zinc oxide (IZO) is formed by sputtering or the like on the photodiode 15, and the film is patterned by photolithography, whereby the electrode 44 is formed.

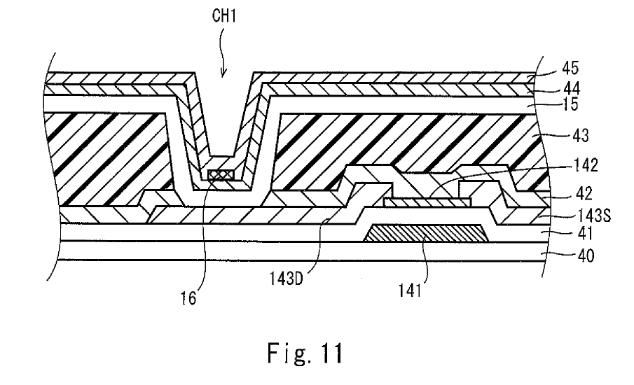

After the electrode 44 is formed, at the step illustrated in FIG. 11, for example, a metal film is formed on the electrode 44 by sputtering or the like, the metal film being obtained by laminating indium zinc oxide (IZO) and molybdenum (Mo). The film is patterned by photolithography, whereby the bias line 16 is formed. Thereafter, a film of silicon oxide (SiO₂) or silicon nitride (SiN) is formed by plasma CVD or the like on the electrode 44 and the bias line 16, whereby the protection film 45 is formed.

The first oxide semiconductor layer 142 in Embodiment 1 described above contains indium, tin, and gallium. The first oxide semiconductor layer 142 has a high acid etching resistance, as compared with an oxide semiconductor containing indium, gallium, and zinc. The source electrode 143S and the drain electrode 143D, therefore, can be formed by wet etching using an etching solution of an inorganic acid containing phosphoric acid, nitric acid, acetic acid, or the like. As a result, as compared with a case where dry etching is performed, etching damage with respect to a surface of the first oxide semiconductor layer 142 that is not in contact with the gate insulating film 41 (the surface on the back channel side) can be reduced.

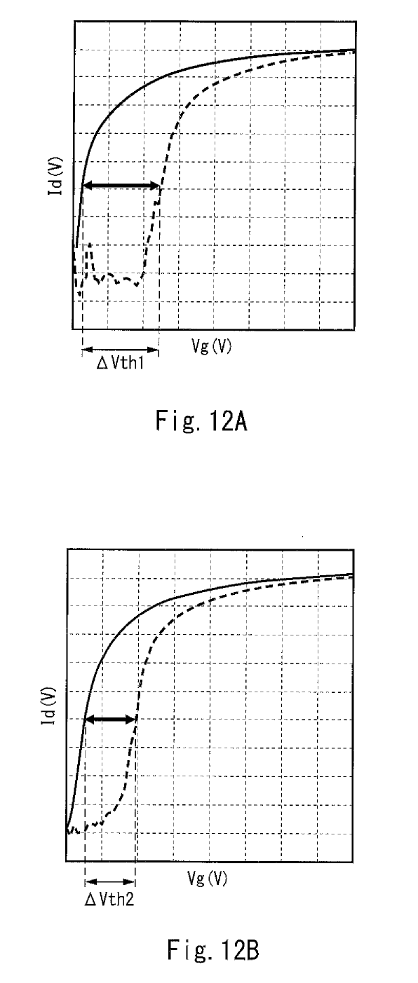

FIGS. 12A and 12B illustrate results of measurement of the shift amount of the threshold voltage of the TFT during X-ray irradiation in the following cases, respectively: a case where the source electrode 143S and the drain electrode 143D are formed by using dry etching; and a case where the source electrode 143S and the drain electrode 143D are formed by using wet etching. In FIGS. 12A and 12B, the broken line indicates the change of the threshold voltage of the TFT before X-ray irradiation, and the solid line indicates the change of the threshold voltage of the TFT after X-ray irradiation.

Let the shift amount of the threshold voltage illustrated in FIG. 12A be ΔVth1, and let the shift amount of the threshold voltage illustrated in FIG. 12B be ΔVth2. In this case, ΔVth1 and ΔVth2 have the relationship expressed as ΔVth2=ΔVth1×0.7. The TFT produced by using wet etching, therefore, has a shift amount of the threshold value during X-ray irradiation that is reduced by about 30%, as compared with the TFT produced by using dry etching.

### Embodiment 2

Embodiment 1 described above is described with reference to an exemplary case where the oxide semiconductor layer in the TFT 14 has a single layer structure composed of the first oxide semiconductor layer 142. The present embodiment is different from Embodiment 1 regarding the point that the oxide semiconductor layer has a laminate structure. Hereinafter, the point different from Embodiment 1 is described.

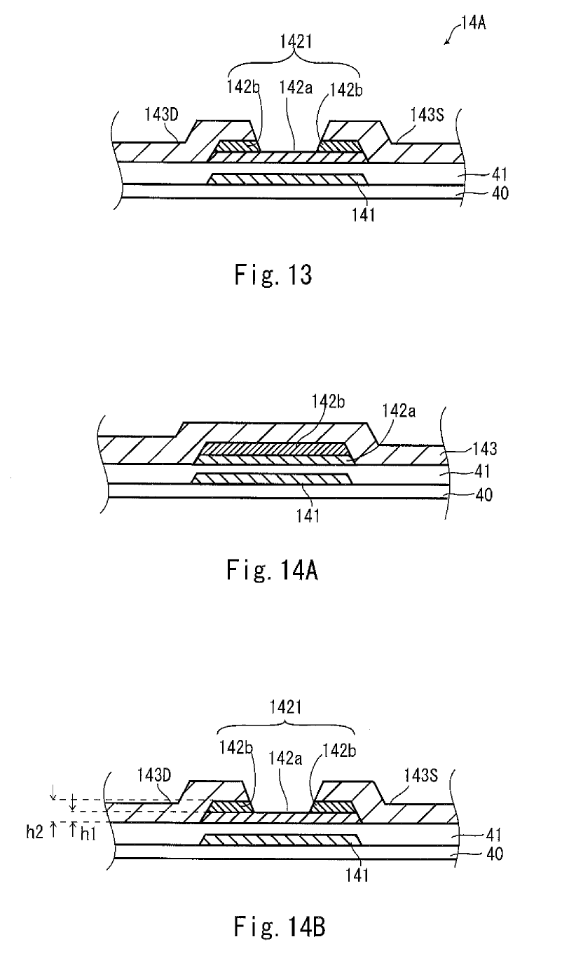

FIG. 13 is a cross-sectional view schematically illustrating the portion of the TFT in the present embodiment. In FIG. 13, configurations identical to those in Embodiment 1 are denoted by the same reference symbols as those in Embodiment 1. As illustrated in FIG. 13, the TFT 14A has an oxide semiconductor layer 1421 that includes a first oxide semiconductor layer 142a and a second oxide semiconductor layer 142b, on a gate electrode 141, with a gate insulating film 41 being interposed therebetween.

The first oxide semiconductor layer 142a is formed with an oxide semiconductor containing indium, tin, and gallium, as is the case with the first oxide semiconductor layer 142 in Embodiment 1.

The second oxide semiconductor layer 142b in this example is formed with, for example, an oxide semiconductor containing indium, gallium, and zinc.

On the second oxide semiconductor layer 142b, a source electrode 143S and a drain electrode 143D are provided.

In the present embodiment, as is the case with Embodiment 1, the source electrode 143S and the drain electrode 143D are formed by performing wet etching. More specifically, as illustrated in FIG. 14A, after the first oxide semiconductor layer 142a is formed, for example, a film of an oxide semiconductor containing indium, gallium, and zinc is formed by sputtering or the like, and the oxide semiconductor is patterned by photolithography, whereby the second oxide semiconductor layer 142b is formed on the first oxide semiconductor layer 142a. Then, for example, a metal film 143 containing aluminum is formed on the second oxide semiconductor layer 142b by sputtering or the like. Subsequently, this metal film 143 is patterned by photolithography, and wet etching is performed by using an etching solution of an inorganic acid containing phosphoric acid, nitric acid, acetic acid, or the like, whereby, as illustrated in FIG. 14B, the source electrode 143S and drain electrode 143D are formed on the second oxide semiconductor layer 142b.

The second oxide semiconductor layer 142b containing indium, gallium, and zinc has a low acid etching resistance, and hence, the second oxide semiconductor layer 142b, other than the portions thereof where the source electrode 143S and the drain electrode 143D, is dissolved by wet etching. On the other hand, the first oxide semiconductor layer 142a containing indium, tin, and gallium has a high acid etching resistance, and hence, is not dissolved by wet etching. As illustrated in FIG. 14B, therefore, the portion of the oxide semiconductor layer between the drain electrode 143D and source electrode 143S has a film thickness h1 smaller than a film thickness h2 in the areas where the drain electrode 143D and the source electrode 143S are formed.

In Embodiment 2, the oxide semiconductor layer 1421 in the TFT 14A has a laminate structure composed of the first oxide semiconductor layer 142a and the second oxide semiconductor layer 142b. In a case where wet etching using the etching solution of an inorganic acid is performed in the step for forming the source electrode 143S and the drain electrode 143D in the TFT 14A, the second oxide semiconductor layer 142b in the area between the source electrode 143S and the drain electrode 143D is dissolved, but the first oxide semiconductor layer 142a is not dissolved, whereby the channel area can be protected by the second oxide semiconductor layer 142b.

Embodiment 2 described above is described with reference to an exemplary case where the second oxide semiconductor layer 142b is formed with an oxide semiconductor containing indium, gallium, and zinc, but the second oxide semiconductor layer 142b is not limited to this. The second oxide semiconductor layer 142b may be formed with, for example, any one of indium tin zinc oxide (ITZO), indium gallium oxide (IGO), indium tungsten oxide (IWO), indium tin gallium oxide (ITGO), indium zinc oxide (IZO), and indium tin oxide (ITO). In other words, the second oxide semiconductor layer 142b is formed with an oxide semiconductor that contains: indium (In); oxygen (O); and at least one of tin (Sn), zinc (Zn), gallium (Ga), and tungsten (W).

### Embodiment 3

Embodiment 1 described above is described with reference to an exemplary case where the source electrode 143S and the drain electrode 143D are formed by carrying out wet etching, whereby etching damage with respect to the oxide semiconductor layer is reduced and the threshold voltage of the TFT 14 is prevented from shifting. Hereinafter, another configuration in which the threshold voltage of the TFT 14 can be prevented from shifting even if the source electrode 143S and the drain electrode 143D are formed by carrying out dry etching is described below as the present embodiment.

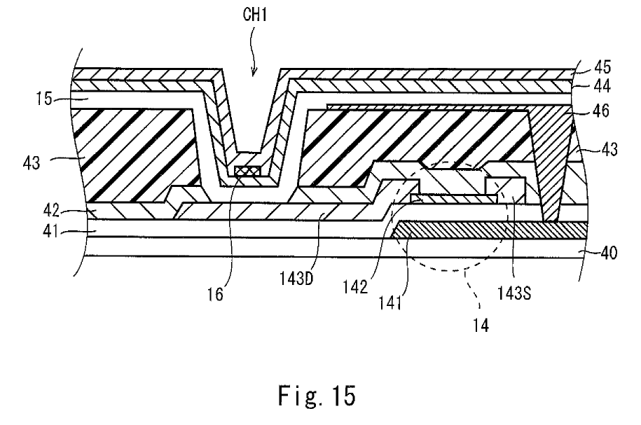

FIG. 15 schematically illustrate a cross section of the pixel 13 in the present embodiment. In FIG. 15, configurations identical to those in Embodiment 1 are denoted by the same reference symbols as those in Embodiment 1. The following description describes different configurations from those in Embodiment 1.

As illustrated in FIG. 15, in the present embodiment, a conductive film 46 is formed, at a position that overlaps the first oxide semiconductor layer 142, with the flattening film 43 and the interlayer insulating film 42 being interposed therebetween, so as to be connected with the gate electrode 141 through a contact hole. The photodiode 15 is provided on the flattening film 43 and the conductive film 46.

The conductive film 46 may be formed with, for example, the same material as that of the gate electrode 141, or alternatively, may be formed with a transparent conductive film of indium tin oxide (ITO), indium zinc oxide (IZO), or the like.

### (Producing Method)

As is the case with Embodiment 1, at the step illustrated in FIG. 6, after the first oxide semiconductor layer 142 is formed, for example, a metal film containing aluminum is formed on the gate insulating film 41, and on the first oxide semiconductor layer 142, by sputtering or the like. Thereafter, in the present embodiment, this metal film is patterned by photolithography and subjected to dry etching, whereby the source electrode 143S and the drain electrode 143D are formed.

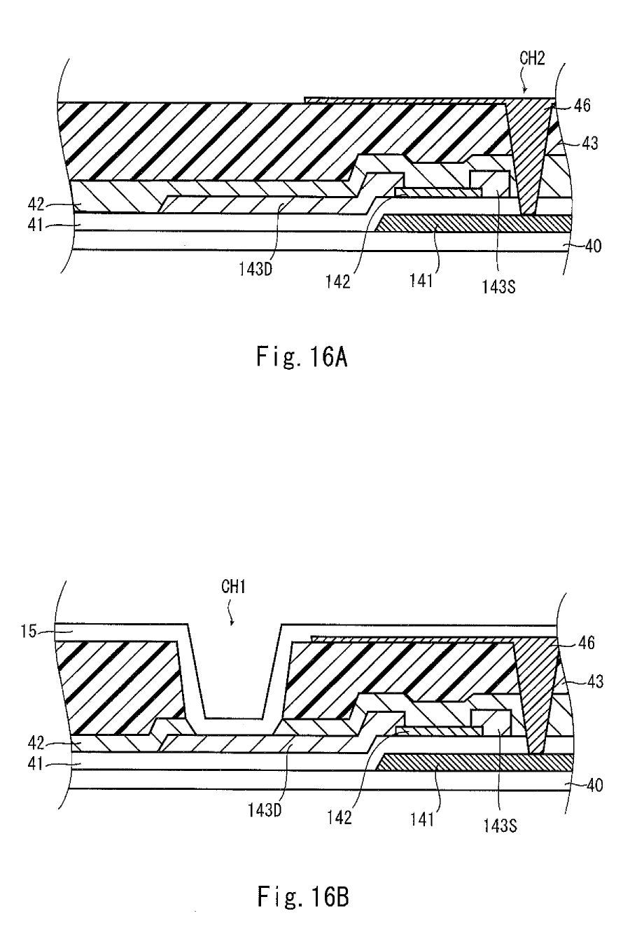

Then, as is the case with the steps illustrated in FIGS. 7 and 8 regarding Embodiment 1, the interlayer insulating film 42 and the flattening film 43 are sequentially formed on the source electrode 143S and the drain electrode 143D. Thereafter, patterning is performed by photolithography, whereby, as illustrated in FIG. 16A, the contact hole CH2 passing through the flattening film 43, the interlayer insulating film 42, and the gate insulating film 41 is formed on the gate electrode 141. Then, for example, a film of aluminum is formed on the flattening film 43 by sputtering or the like, and the conductive film 46 is formed so as to overlap the first oxide semiconductor layer 142. With this configuration, the conductive film 46 is connected with the gate electrode 141 through the contact hole CH2.

Subsequently, as illustrated in FIG. 16B, patterning is performed by photolithography, whereby the contact hole CH1 passing through the flattening film 43 and the interlayer insulating film 42 is formed on the drain electrode 143D. Then, films of the n-type amorphous silicon layer, the intrinsic amorphous silicon layer, and the p-type amorphous silicon layer are formed in the stated order on the flattening film 43 and the conductive film 46 by sputtering or the like. Thereafter, patterning by photolithography is performed, followed by dry etching, whereby the photodiode 15 is formed. After the photodiode 15 is formed, in the same manner as that in the steps illustrated in FIGS. 10, 11 regarding Embodiment 1, the bias line 16, the electrode 44, and the protection film 45 are formed.

In Embodiment 3 described above, dry etching is performed in order to form the source electrode 143S and the drain electrode 143D. The dry etching causes etching damage to the surface (on the back channel side) of the first oxide semiconductor layer 142, thereby causing defect levels to be formed on the back channel side, which causes the threshold value of the TFT 14 to tend to shift. In Embodiment 3, however, as illustrated in FIG. 15, the conductive film 46, connected with the gate electrode 141, is provided. In a case where, for example, the TFT 14 is an n channel type TFT, therefore, when a positive voltage is applied to the gate electrode 141, holes are trapped on the back channel side of the TFT 14, electrons are induced at the interface between the flattening film 43 and the interlayer insulating film 42. As a result, holes trapped on the back channel side are recombined with the electrons induced at the interface between the flattening film 43 and the interlayer insulating film 42, whereby the holes trapped on the back channel side are reduced.

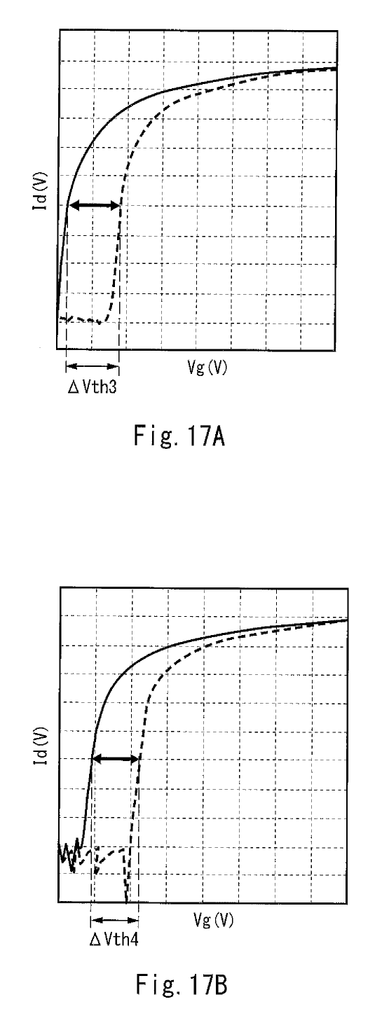

Here, FIGS. 17A and 17B illustrate results of measurement of the shift amount of the threshold voltage of the TFT during X-ray irradiation in a case where the source electrode 143S and the drain electrode 143D are formed by using dry etching, regarding the following cases, respectively: a case where the conductive film 46 is not provided; and a case where the conductive film 46 is provided. In FIGS. 17A and 17B, the broken line indicates the change of the threshold voltage of the TFT before X-ray irradiation, and the solid line indicates the change of the threshold voltage of the TFT after X-ray irradiation.

Let the shift amount of the threshold voltage illustrated in FIG. 17A be ΔVth3, and let the shift amount of the threshold voltage illustrated in FIG. 17B be ΔVth4. In this case, ΔVth3 and ΔVth4 have the relationship expressed as ΔVth4=ΔVth3×0.8. The TFT 14 for which the conductive film 46 is provided, therefore, have a shift amount of the threshold value during X-ray irradiation that is reduced by about 20%, as compared with the TFT for which the conductive film 46 is not provided.

Further, the first oxide semiconductor layer 142 in the TFT 14 is formed with an oxide semiconductor that contains indium, tin, and gallium. Since the first oxide semiconductor layer 142 has a higher electron mobility, as compared with a case where it is formed with an oxide semiconductor containing indium, gallium, and zinc, the amount of irradiated X-ray can be reduced, as compared with the case where an oxide semiconductor containing indium, gallium, and zinc is used for forming the TFT 14.

### Embodiment 4

Embodiment 3 described above is described with reference to an exemplary case where the oxide semiconductor layer in the TFT 14 has a single layer structure composed of the first oxide semiconductor layer 142. The present embodiment is different from Embodiment 3 regarding the point that the oxide semiconductor layer of the TFT 14 has a laminate structure composed of the first oxide semiconductor layer 142a and the second oxide semiconductor layer 142b as is the case with Embodiment 2. Hereinafter, the point different from Embodiment 3 is described.

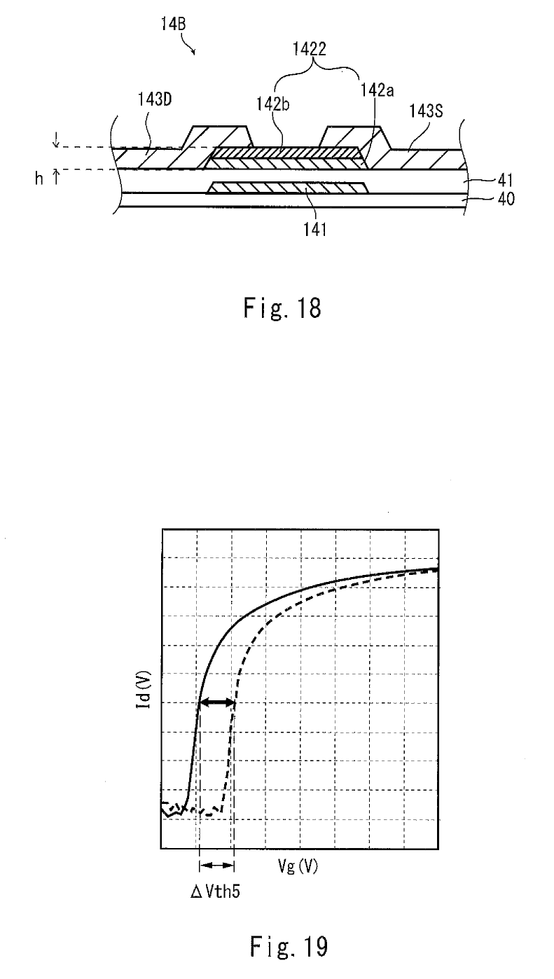

FIG. 18 is a cross-sectional view schematically illustrating the portion of the TFT in the present embodiment. In FIG. 18, configurations identical to those in Embodiment 1 are denoted by the same reference symbols as those in Embodiment 1. As illustrated in FIG. 18, the TFT 14B has such a configuration that an oxide semiconductor layer 1422 that includes a first oxide semiconductor layer 142a and a second oxide semiconductor layer 142b gate is formed on a gate electrode 141, with an insulating film 41 being interposed therebetween.

In the present embodiment, the source electrode 143S and the drain electrode 143D formed by carrying out dry etching are provided on the second oxide semiconductor layer 142b. In the case where dry etching is used, the film thickness h of the oxide semiconductor layer 1422 in areas where the source electrode 143S and the drain electrode 143D are formed, and the film thickness h thereof where the source electrode 143S formed and the drain electrode 143D are not formed, are approximately the same, unlike Embodiment 2 in which the source electrode 143S and the drain electrode 143D are formed by using wet etching (see FIGS. 13, 14B).

Etching damage occurs to the surface of the second oxide semiconductor layer 142b when dry etching is carried out, but the first oxide semiconductor layer 142a is protected by the second oxide semiconductor layer 142b. The channel area of the TFT 14B, therefore, is not damaged by dry etching, and the threshold voltage of the TFT 14B during X-ray irradiation can be prevented from shifting.

### MODIFICATION EXAMPLE

Embodiments of the present invention are described above, but these embodiments described are merely examples for implementing the present invention. The present invention, therefore, is not limited by the embodiments described above at all, and the above-described embodiments can be appropriately changed and implemented within a range that is not deviated from the scope of the invention. The following description describes modification examples of the present invention.

(1) In Embodiment 1 or Embodiment 2 described above, a conductive film 46 identical to that in Embodiment 3 may be provided. With such a configuration, defect levels formed on the back channel side of the TFT 14 or 14A can be reduced, whereby the shift amount of the threshold of the TFT 14 or 14B can be reduced further, as compared with Embodiments 1 and 2.

(2) Embodiments 3 and 4 described above are described with reference to an exemplary case where dry etching is carried out when the source electrode 143S and the drain electrode 143D are formed, but wet etching may be carried out in place of dry etching for forming the source electrode 143S and the drain electrode 143D.

With such a configuration, in the case of Embodiment 3, that is, in the case where the oxide semiconductor layer of the TFT 14 has a single layer structure formed with the first oxide semiconductor layer 142, etching damage occurring on the surface of the first oxide semiconductor layer 142 is reduced as compared with the case where dry etching is carried out, and the shift amount of the threshold voltage of the TFT 14 during X-ray irradiation can be reduced further.

Still further, in the case of Embodiment 4, that is, in the case where the oxide semiconductor layer of the TFT 14B has a laminate structure composed of the first oxide semiconductor layer 142a and the second oxide semiconductor layer 142b, a part of the second oxide semiconductor layer 142b is dissolved by wet etching that uses an acid etching solution. The first oxide semiconductor layer 142a, however, is not dissolved by wet etching, and hence, the channel area can be protected by the second oxide semiconductor layer 142b. As a result, as compared with Embodiment 4, the shift amount of the threshold voltage of the TFT during X-ray irradiation can be reduced.

(3) Embodiments 3 and 4 described above are described with reference to an exemplary case where the conductive film 46 is formed with a material equivalent to that of the gate electrode 141, and is electrically connected with gate electrode 141. The configuration, however, may be such that the conductive film 46 is formed with a material equivalent to that of the source electrode 143S, and is electrically connected with the source electrode 143S. In the case of this configuration, the conductive film 46 has the same potential as that of the source electrode 143S. Carriers induced by the potential of the conductive film 46 at the interface between the flattening film 43 and the interlayer insulating film 42, and carriers trapped by the defect levels formed on the back channel side of the TFT 14, 14B are recombined, whereby the carriers trapped on the back channel side can be reduced.

FIG. 19 illustrates results of measurement of the shift amount of the threshold voltage of a TFT during X-ray irradiation, the TFT being configured so that the source electrode 143S thereof is connected to the conductive film 46. In FIG. 19, the broken line indicates the change of the threshold voltage of the TFT before X-ray irradiation, and the solid line indicates the change of the threshold voltage of the TFT after X-ray irradiation. Let the shift amount of the threshold voltage illustrated in FIG. 19 be ΔVth5. In this case, ΔVth5 and ΔVth3 indicating the shift amount of the threshold voltage of the TFT for which the conductive film 46 is not provided (see FIG. 17A) satisfy the relationship given as ΔVth5=ΔVth3×0.7. Thus, the TFT for which the conductive film 46 connected to the source electrode 143S is provided has a shift amount of the threshold value during X-ray irradiation that is reduced by about 30%, as compared with the TFT for which the conductive film 46 is not provided. Further, the shift amount of the threshold voltage of the TFT in the present modification example during X-ray irradiation is reduced by about 10% as compared with the shift amount of the threshold voltage of the TFT in Embodiment 3 described above, that is, the TFT 14 for which the conductive film 46 connected to the gate electrode 141 of the TFT 14 is provided (see FIG. 17B).

(4) Still further, Embodiments 3 and 4 described above are described with reference to an exemplary case where the conductive film 46 is provided on the flattening film 43, but the configuration may be such that the flattening film 43 is not provided and the conductive film 46 is provided on the interlayer insulating film 42. This configuration makes the distance between the conductive film 46 and the oxide semiconductor layer 142 smaller. As a result, carriers (holes) trapped on the back channel side of the TFT 14, 14B, and carriers (electrons) induced at the interface of the interlayer insulating film 42 tend to be recombined, whereby the carriers trapped on the back channel side of the TFT 14, 14B can be reduced further.

### DESCRIPTION OF REFERENCE NUMERALS

1: X-ray imaging device
10: imaging panel
10A: scintillator
11: gate line
12: data line
13: pixel
14: thin film transistor (TFT)
15: photodiode
16: bias line
20: control unit
20A: gate control part
20B: signal reading part
20C: image processing part
20D: voltage control part
20E: timing control part
30: X-ray source
41: gate insulating film
42: interlayer insulating film
43: flattening film
44: upper electrode
45: protection film
46: conductive film
141: gate electrode
142: oxide semiconductor layer, first oxide semiconductor layer
142a: first oxide semiconductor layer (ITZO layer)
142b: second oxide semiconductor layer
143S: source electrode
143D: drain electrode

1. An imaging panel comprising:
an imaging part that includes a pixel that receives X-ray and outputs charges corresponding to the received X-ray; and
a thin film transistor for reading out the charges at the pixel,
wherein the thin film transistor includes:
a gate;
an oxide semiconductor layer; and
a source and a drain formed on a part of the oxide semiconductor layer, the source and the drain being formed by wet etching with respect to a metal film formed on the oxide semiconductor layer,
wherein the oxide semiconductor layer includes an ITZO layer that contains indium, tin, gallium, and oxygen.

2. The imaging panel according to claim 1,
wherein the oxide semiconductor layer further includes a semiconductor layer that is provided on the ITZO layer and contains indium and oxygen, as well as at least one of tin, zinc, gallium, and tungsten.

3. The imaging panel according to claim 1, further comprising:
an insulating film provided on the thin film transistor; and
a conductive part provided at a position opposed to the thin film transistor, in an upper layer above the insulating film, the conductive part being connected with the gate or the source through a contact hole formed in the insulating film.

4. An imaging panel comprising:
an imaging part that includes a pixel that receives X-ray and outputs charges corresponding to the received X-ray;
a thin film transistor for reading out the charges at the pixel;
an insulating film provided on the thin film transistor; and
a conductive part provided at a position opposed to the thin film transistor, in an upper layer above the insulating film,
wherein the thin film transistor includes:
a gate;
an oxide semiconductor layer;
a source provided on the oxide semiconductor layer; and
a drain provided on the oxide semiconductor layer,
wherein the oxide semiconductor layer includes an ITZO layer that contains indium, tin, gallium, and oxygen, and
the conductive part is connected with the gate or the source through a contact hole formed in the insulating film.

5. The imaging panel according to claim 4,
wherein the oxide semiconductor layer further includes a semiconductor layer that is provided on the ITZO layer and contains indium and oxygen, as well as at least one of tin, zinc, gallium, and tungsten.

6. An X-ray imaging device comprising:
the imaging panel according to claim 1;
an X-ray source that projects X-ray to the imaging panel; and
a control unit that controls a gate voltage of the thin film transistor in the imaging panel, and reads out a signal corresponding to charges generated at the pixel in the imaging panel.
